(19) United States
(12) Patent Application Publication
(10) Pub. No.: US 2025/0079297 A1
(43) Pub. Date: Mar. 6, 2025

(54) SEMICONDUCTOR DEVICES

(71) Applicant: Samsung Electronics Co., Ltd., Suwon-si (KR)

(72) Inventor: Ilsup Kim, Suwon-si (KR)

(21) Appl. No.: 18/659,091

(22) Filed: May 9, 2024

(30) Foreign Application Priority Data
Aug. 29, 2023 (KR) 10-2023-0113518

(51) Int. Cl. H01L 23/522; H01L 21/3213; H01L 21/768; H01L 23/532; H01L 29/06; H01L 29/417; H01L 29/423; H01L 29/775

(52) U.S. Cl. CPC H01L 23/5226; H01L 21/32135; H01L 21/32139; H01L 21/76895; H01L 23/53252; H10D 30/43; H10D 30/6729; H10D 30/6735; H10D 62/121

(57) ABSTRACT

A semiconductor device includes a lower structure, a plurality of conductive wirings on the lower structure, an interlayer insulating layer on the lower structure and on side surfaces of the plurality of conductive wirings, a protective insulating layer on the interlayer insulating layer and the plurality of conductive wirings, and an upper insulating structure. The upper insulating structure includes an upper interlayer portion on the protective insulating layer, and a first extension portion extending from the upper interlayer portion, penetrating through the protective insulating layer, the interlayer insulating layer, and a first conductive wiring among the plurality of conductive wirings, and extending into the lower structure.

### CROSS-REFERENCE TO RELATED APPLICATION(S)

This application claims the benefit under 35 U.S.C. § 119(a) of Korean Patent Application No. 10-2023-0113518, filed on Aug. 29, 2023, in the Korean Intellectual Property Office, the entire disclosure of which is incorporated herein by reference for all purposes.

### BACKGROUND

The present inventive concept relates to semiconductor devices.

In semiconductor devices such as logic circuits and memories, interconnection structures (e.g., back end of line (BEOL)) connecting various conductive elements located at different levels, such as conductive lines in the back end of line (BEOL) or contact plugs connected to active regions such as source and drain may be used. As semiconductor devices are more highly integrated, line widths and/or pitches decrease, and efforts are being made to develop other processes in addition to the Damascene process.

### SUMMARY

Example embodiments provide semiconductor devices having improved integration and electrical characteristics.

According to example embodiments, a semiconductor device includes a lower structure; a plurality of conductive wirings on the lower structure; an interlayer insulating layer on the lower structure and on side surfaces of the plurality of conductive wirings; a protective insulating layer on the interlayer insulating layer and the plurality of conductive wirings; and an upper insulating structure. The upper insulating structure includes an upper interlayer portion on the protective insulating layer, and an extension portion extending from the upper interlayer portion, penetrating through the protective insulating layer, the interlayer insulating layer, and a first conductive wiring among the plurality of conductive wirings, and extending into the lower structure.

According to example embodiments, a semiconductor device includes a lower structure; a conductive wiring on the lower structure; an interlayer insulating layer on the lower structure and disposed on a side surface of the conductive wiring; and an upper insulating structure including an upper interlayer portion on the interlayer insulating layer, and an extension portion extending from the upper interlayer portion, penetrating through the interlayer insulating layer and the conductive wiring and dividing the conductive wiring into a first wiring portion and a second wiring portion spaced apart from each other.

According to example embodiments, a semiconductor device includes a lower structure including a substrate, a gate, an active region, a source/drain region, a lower insulating layer, and a contact plug; a conductive wiring on the lower structure; an interlayer insulating layer on the lower structure and on a side surface of the conductive wiring; a protective insulating layer on the interlayer insulating layer and the conductive wiring; and an upper insulating structure including an upper interlayer portion on the protective insulating layer, and an extension portion extending from the upper interlayer portion, penetrating through the protective insulating layer and the conductive wiring, and extending into an interior of the lower structure. The active region is on the substrate, the gate is provided on the active region and crosses the active region, the source/drain region is on at least one side of the gate and is disposed on the active region, the lower insulating layer covers at least a portion of the source/drain region, and the contact plug is on the source/drain region and is electrically connected to the conductive wiring.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a plan view illustrating a semiconductor device according to example embodiments;

FIGS. 2 and 3 are cross-sectional views illustrating a semiconductor device according to example embodiments;

FIG. 4 is a cross-sectional view illustrating a semiconductor device according to example embodiments;

FIG. 5 is a cross-sectional view illustrating a semiconductor device according to example embodiments;

FIG. 6 is a cross-sectional view illustrating a semiconductor device according to example embodiments;

FIG. 7 is a plan view illustrating a semiconductor device according to example embodiments;

FIG. 8 is a cross-sectional view illustrating a semiconductor device according to example embodiments;

FIGS. 9A to 9B are cross-sectional views illustrating a semiconductor device according to example embodiments; and

FIGS. 10 to 18 are diagrams illustrating a process sequence to describe a method of manufacturing a semiconductor device according to example embodiments.

### DETAILED DESCRIPTION

Hereinafter, example embodiments will be described with reference to the attached drawings. Like reference characters refer to like elements throughout.

Hereinafter, terms such as ‘on’, ‘upper portion’, ‘upper surface’, ‘below’, ‘lower portion’, ‘lower surface’, ‘side’, and the like may be understood as referring to the drawings, except that otherwise indicated by reference numerals.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

Terms such as “same,” “equal,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to emphasize this meaning, unless the context or other statements indicate otherwise.

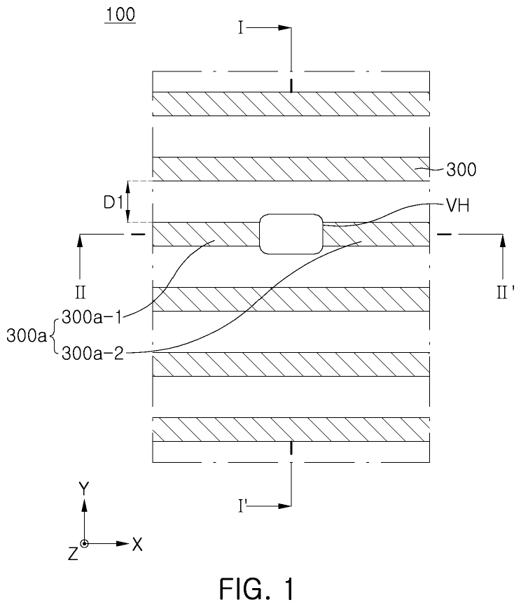

FIG. 1 is a plan view illustrating a semiconductor device according to example embodiments.

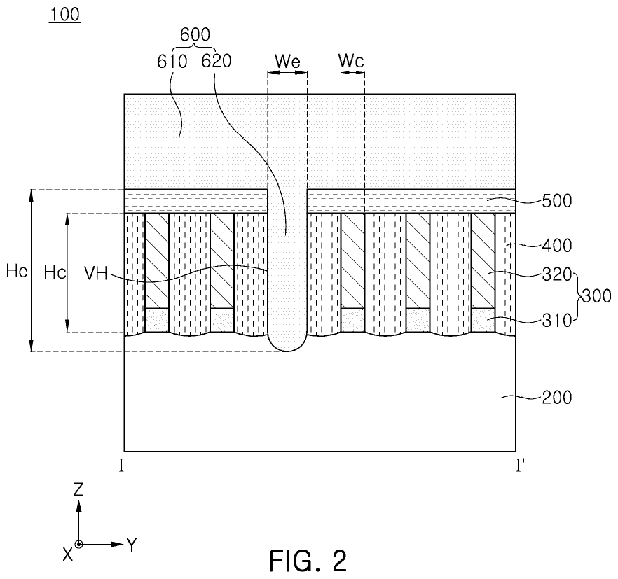

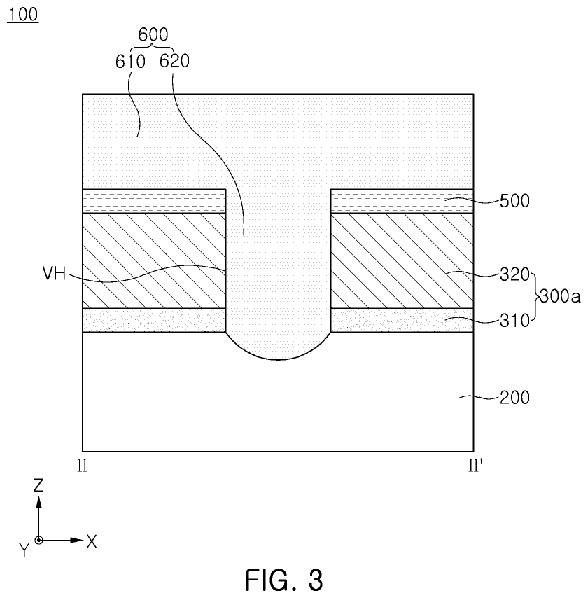

FIGS. 2 and 3 are cross-sectional views illustrating a semiconductor device according to example embodiments. FIGS. 2 and 3 illustrate cross-sections of the semiconductor device of FIG. 1 along cutting lines I-I′ and II-II′, respectively. For convenience of explanation, only some components of the semiconductor device are illustrated in FIG. 1.

Referring to FIGS. 1 to 3, a semiconductor device 100 may include a lower structure 200, a plurality of conductive wirings 300, an interlayer insulating layer 400, a protective insulating layer 500, and an upper insulating structure 600. Each of the plurality of conductive wirings 300 may include a barrier layer 310 and a wiring layer 320.

The lower structure 200 may have an upper surface extending in the X- and Y-directions. The lower structure 200 may include an insulating material. For example, the lower structure 200 may be formed of or include Flowable Oxide (FOX), Tonen SilaZen (TOSZ), Undoped Silica Glass (USG), Borosilica Glass (BSG), PhosphoSilaca Glass (PSG), BoroPhosphoSilica Glass (BPSG), Plasma Enhanced Tetra Ethyl Ortho Silicate (PETEOS), Fluoride Silicate Glass (FSG), High Density Plasma (HDP) oxide, Plasma Enhanced Oxide (PEOX), Flowable CVD (FCVD) oxide, or combinations thereof.

The plurality of conductive wirings 300 may be disposed on the lower structure 200. The plurality of conductive wirings 300 may contact an upper surface of the lower structure 200. The plurality of conductive wirings 300 may extend lengthwise in a first direction (e.g., X-direction) and may be arranged to be spaced apart from each other in a second direction (e.g., Y-direction) that intersects the first direction. The second direction may be perpendicular to the first direction. The minimum distance D1 at which the plurality of conductive wirings 300 are spaced apart from each other in the second direction (e.g., Y-direction) may be about 24 nm or less. Depending on an example embodiment, the minimum distance D1 at which the plurality of conductive wirings 300 are spaced apart from each other in the second direction may be about 18 nm or less or about 12 nm or less. The plurality of conductive wirings 300 may have a line shape or a bar shape extending in the X-direction.

The plurality of conductive wirings 300 may include a conductive material. For example, each of the plurality of conductive wirings 300 may be formed of or include at least one of titanium nitride (TiN), tantalum nitride (TaN), tungsten nitride (WN), tungsten carbon nitride (WCN), aluminum (Al), cobalt (Co), titanium (Ti), tantalum (Ta), nickel (Ni), Tungsten (W), molybdenum (Mo), platinum (Pt), ruthenium (Ru), and iridium (Ir). For example, the plurality of conductive wirings 300 may include at least one noble metal material selected from the group consisting of platinum (Pt), ruthenium (Ru), and iridium (Ir).

Each of the plurality of conductive wirings 300 may include a barrier layer 310 and a wiring layer 320 disposed on the barrier layer 310. The wiring layer 320 may contact an upper surface of the barrier layer 310. The barrier layer 310 may include metal nitride, and depending on an example embodiment, the barrier layer 31 may be formed of or include titanium nitride (TiN). The wiring layer 320 may include a metal material, and depending on an example embodiment, the wiring layer 320 may be formed of or include ruthenium (Ru). For example, when the width of each of the plurality of conductive wirings 300 is formed to be 24 nm or less, as the wiring layer 320 contains ruthenium (Ru), the electrical characteristics may be improved compared to the case in which the wiring layer 320 contains only copper (Cu).

The interlayer insulating layer 400 may be disposed on the side surfaces of the plurality of conductive wirings 300 on the lower structure 200. The interlayer insulating layer 400 may contact the side surfaces of the plurality of conductive wirings 300. The interlayer insulating layer 400 may contact an upper surface of the lower structure 200. The interlayer insulating layer 400 may have a lower surface extending into the lower structure 200. Accordingly, the lower end of the interlayer insulating layer 400 may be disposed at a lower level than the lower ends of the plurality of conductive wirings 300. For example, a lower surface of the interlayer insulating layer 400 may be at a lower level than an upper surface of the lower structure 200 located below the conductive wirings 300. The upper surface of the interlayer insulating layer 400 may be located at substantially the same level as the upper surface of the plurality of conductive wirings 300. For example, the upper surface of the interlayer insulating layer 400 may be coplanar with the upper surface of the plurality of conductive wirings 300.

The interlayer insulating layer 400 may include at least one of low-κ dielectric, oxide, nitride, and oxynitride, and may be formed of or include silicon oxide, silicon oxynitride, SiOC, SiCOH, or combinations thereof.

A low-κ dielectric material may be defined as a material with a lower dielectric constant than silicon oxide (e.g., SiO₂). Depending on an example embodiment, the interlayer insulating layer 400 may include porous silicon oxide having pores.

The protective insulating layer 500 may be disposed on the plurality of conductive wirings 300 and the interlayer insulating layer 400. The protective insulating layer 500 may contact upper surfaces of the plurality of conductive wirings 300 and the interlayer insulating layer 400. The protective insulating layer 500 may be formed of or include, for example, silicon oxide, silicon nitride, silicon oxynitride, or combinations thereof. Depending on an example embodiment, the protective insulating layer 500 may include a material different from the material of the interlayer insulating layer 400. Depending on an example embodiment, when the interlayer insulating layer 400 includes a low-κ dielectric material, the protective insulating layer 500 may include an insulating material having a higher dielectric constant than the interlayer insulating layer 400.

The upper insulating structure 600 may include the upper interlayer portion 610 on the protective insulating layer 500, and an extension portion 620 extending from the upper interlayer portion 610 and extending into the lower structure 200 through the protective insulating layer 500, the interlayer insulating layer 400, and one of the plurality of conductive wirings 300. For example, the upper interlayer portion 610 may contact an upper surface of the protective insulating layer 500, and the extension portion 620 may contact an upper surface of the lower structure 200 and side surfaces of the protective insulating layer 500, the interlayer insulating layer 400, and one of the plurality of conductive wirings 300. The extension portion 620 may be arranged to fill the interior of the via hole VH extending into the lower structure 200 through the protective insulating layer 500 and one of the plurality of conductive wirings 300. Depending on an example embodiment, the via hole (VH) and the extension portion 620 that fills the via hole (VH) may be arranged to simultaneously penetrate several of the plurality of conductive wirings 300.

The height He of the extension portion 620 may be greater than the height He of each of the plurality of conductive wirings 300. The width We of the extension portion 620 may be greater than the width We of each of the plurality of conductive wirings 300. The lower end of the extension portion 620 may be located at a lower level than the lower end of the interlayer insulating layer 400. The height He of the extension portion 620 may be greater than a height of the interlayer insulating layer 400. The width of at least some of the plurality of conductive wirings 300 may be smaller than the width of the extension portion 620.

The upper insulating structure 600 may include an extension portion 620 that penetrates the first conductive wiring 300a among the plurality of conductive wirings 300 and extends into the interior of the lower structure 200. The extension portion 620 may contact the side surfaces of the first conductive wiring 300a, and the extension portion 620 may contact the side surfaces of the barrier layer 310 and the wiring layer 320 of the first conductive wiring 300a. The first conductive wiring 300a may be divided into a first wiring portion 300a-1 and a second wiring portion 300a-2 spaced apart from each other by the extension portion 620. The width of each of the first wiring portion 300a-1 and the second wiring portion 300a-2 in the second direction (for example, Y-direction) may be smaller than the width of the extension portion 620 in the second direction (e.g., Y-direction). Each of the first wiring portion 300a-1 and the second wiring portion 300a-2 may have a bar shape or a line shape extending in the first direction (e.g., X-direction).

Each of the first wiring portion 300a-1 and the second wiring portion 300a-2 may include a barrier layer 310 and a wiring layer 320 on the barrier layer 310. The barrier layers 310 may include a first conductive material, and the wiring layers 320 may include a second conductive material different from the first conductive material. The extension portion 620 may contact side surfaces of the barrier layers 310 and side surfaces of the wiring layers 320. Depending on an example embodiment, the second conductive material may be formed of or include ruthenium (Ru).

The upper insulating structure 600 may include, for example, at least one of low-κ dielectric, oxide, nitride, and oxynitride, and may be formed of or include silicon oxide, silicon oxynitride, SiOC, SiCOH, or combinations thereof.

The upper insulating structure 600 may include a low-κ dielectric material. Depending on an example embodiment, the upper insulating structure 600 may include a material in which at least one of fluorine (F), carbon (C), or methyl group (CH₃) is bonded to silicon oxide. Depending on an example embodiment, the upper insulating structure 600 may include porous silicon oxide having pores.

In the description of the following embodiments, content identical to the above-described content is not repeated.

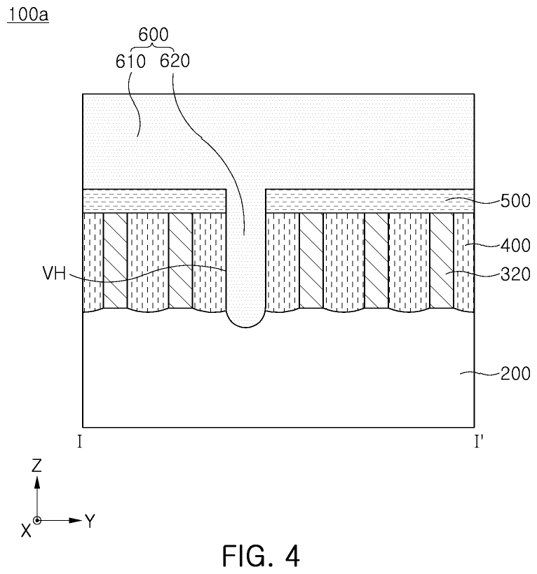

FIG. 4 is a cross-sectional view illustrating a semiconductor device according to example embodiments.

Referring to FIG. 4, in a semiconductor device 100a, each of the plurality of conductive wirings may be composed of only the wiring layer 320 without the barrier layer 310. Accordingly, the wiring layer 320 may directly contact the lower structure 200. In the embodiment of FIG. 4, the wiring layer 320 may have a height Hc.

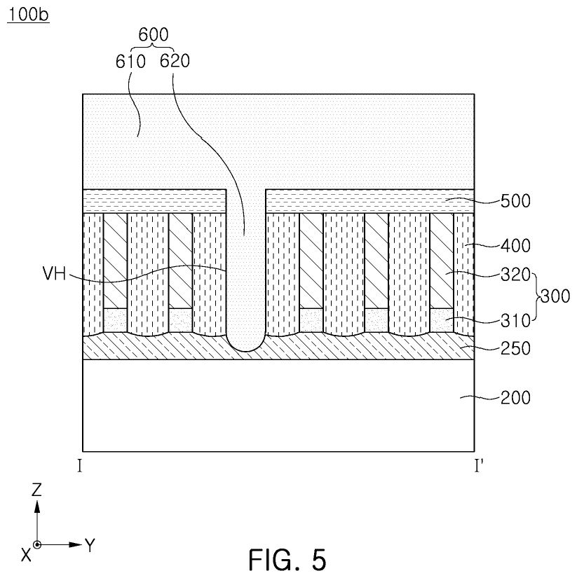

FIG. 5 is a cross-sectional view illustrating a semiconductor device according to example embodiments.

Referring to FIG. 5, a semiconductor device 100b may further include an etch stop layer 250 disposed between the lower structure 200 and the interlayer insulating layer 400. A plurality of conductive wirings 300 may be disposed on the etch stop layer 250, and the interlayer insulating layer 400 may be disposed on the etch stop layer 250 to cover the side surfaces of the plurality of conductive wirings 300. The interlayer insulating layer 400, the plurality of conductive wirings 300, and the extension portion 620 may contact an upper surface of the etch stop layer 250. The interlayer insulating layer 400 may have a lower surface extending into the interior of the etch stop layer 250. The extension portion 620 of the upper insulating structure 600 may extend into the interior of the etch stop layer 250 by penetrating through the protective insulating layer 500, the interlayer insulating layer 400, and some of the plurality of conductive wirings 300. The height He of the extension portion 620 may be greater than the height He of each of the plurality of conductive wirings 300. The etch stop layer 250 may be an insulating layer containing an insulating material such as silicon oxide, silicon nitride, or silicon oxynitride. Depending on an example embodiment, the etch stop layer 250 may be a conductive layer containing a conductive material such as metal, metal nitride, or metal silicide nitride film. Depending on an example embodiment, the etch stop layer 250 may be formed to include a material such as polysilicon.

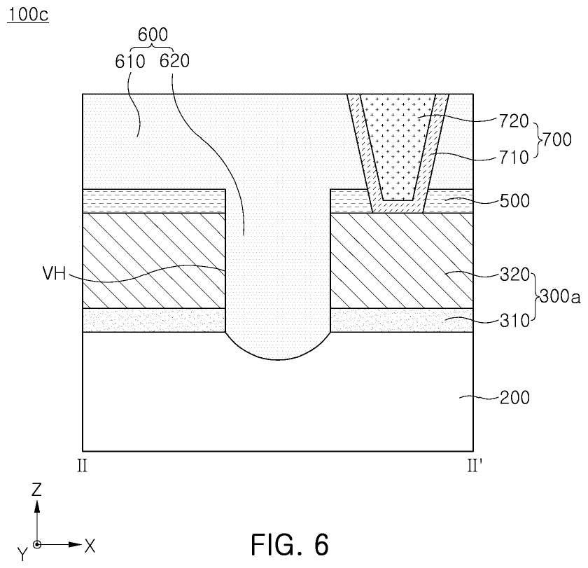

FIG. 6 is a cross-sectional view illustrating a semiconductor device according to example embodiments.

Referring to FIG. 6, a semiconductor device 100c may further include an upper conductive structure 700 that penetrates the upper interlayer portion 610 and the protective insulating layer 500 and is electrically connected to one conductive wiring among the plurality of conductive wirings 300. Each of the plurality of conductive wirings 300 may include a barrier layer 310 and a wiring layer 320 on the barrier layer 310, and the upper conductive structure 700 may include a second barrier layer 710 and a second wiring layer 720 on the second barrier layer 710. The second barrier layer 710 may cover the side and lower surfaces of the second wiring layer 720, and the second wiring layer 720 may be spaced apart from the upper insulating structure 600 by the second barrier layer 710. For example, the second barrier layer 710 may contact the side and lower surfaces of the second wiring layer 720. The upper interlayer portion 610 and the protective insulating layer 500 may contact side surfaces of the second barrier layer 710, and a lower surface of the second barrier layer 710 may contact an upper surface of the wiring layer 320. Upper surfaces of the upper interlayer portion 610, the second barrier layer 710, and the second wiring layer 720 may be coplanar with each other. The extension portion 620 may contact side surfaces of the barrier layers 310 and side surfaces of the wiring layers 320. The barrier layers 310 may include a first conductive material, and the wiring layers 320 may include a second conductive material different from the first conductive material. Depending on an example embodiment, the second wiring layer 720 may include a conductive material different from the second conductive material. Depending on an example embodiment, the second conductive material may be formed of or include ruthenium (Ru). Depending on an example embodiment, the second wiring layer 720 may include a conductive material different from the second conductive material. Referring to FIGS. 1 to 3 together, the upper conductive structure 700 may be electrically connected to at least one of the first wiring portion 300a-1 and the second wiring portion 300a-2.

The upper conductive structure 700 may include a plurality of upper wirings located at different levels. The upper conductive structure 700 may include a via portion that penetrates the protective insulating layer 500 and contacts the plurality of conductive wirings 300. The upper conductive structure 700 may be formed of or include at least one of copper (Cu), ruthenium (Ru), and titanium (Ti).

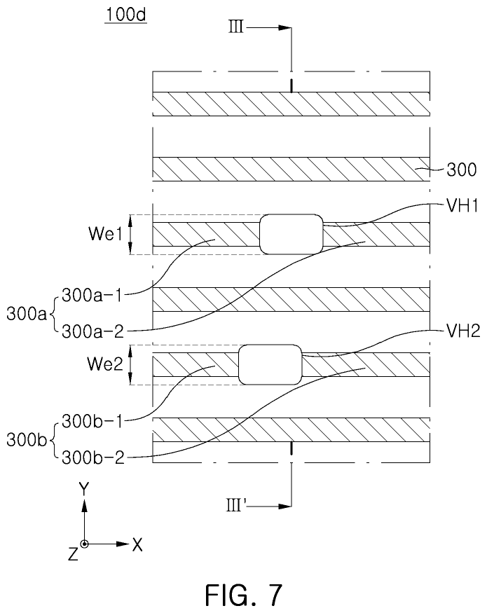

FIG. 7 is a plan view illustrating a semiconductor device according to example embodiments.

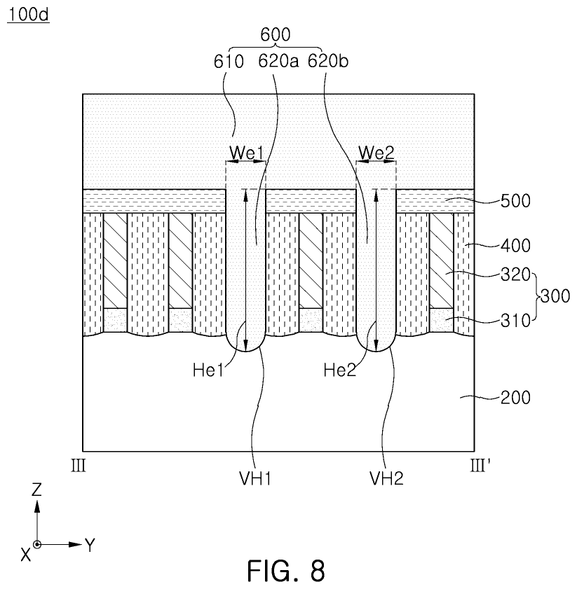

FIG. 8 is a cross-sectional view illustrating a semiconductor device according to example embodiments. FIG. 8 illustrates cross sections of the semiconductor device of FIG. 7 along the cutting line III-III′. For convenience of explanation, only some components of the semiconductor device are illustrated in FIG. 7.

Referring to FIGS. 7 to 8, the upper insulating structure 600 may include a plurality of extension portions, and the plurality of extension portions may include a first extension portion 620a and a second extension portion 620b. The first extension portion 620a may penetrate the first conductive wiring 300a among the plurality of conductive wirings 300 and divide the first conductive wiring 300a, and the second extension portion 620b may penetrate the second conductive wiring 300b among the plurality of conductive wirings 300 and divide the second conductive wiring 300b. The first conductive wiring 300a may be divided into a first wiring portion 300a-1 and a second wiring portion 300a-2 spaced apart from each other by the first extension portion 620a. The second conductive wiring 300b may be divided into a third wiring portion 300b-1 and a fourth wiring portion 300b-2 spaced apart from each other by the second extension portion 620b.

The height He1 of the first extension portion 620a and the height of the second extension portion 620b may be substantially the same, but are not limited thereto. Depending on an example embodiment, the height He1 of the first extension portion 620a and the height He2 of the second extension portion 620b may be different. The width We1 of the first extension portion 620a and the width We2 of the second extension portion 620b may be substantially the same, but are not limited thereto. Depending on an example embodiment, the width We1 of the first extension portion 620a and the width We2 of the second extension portion 620b may be different.

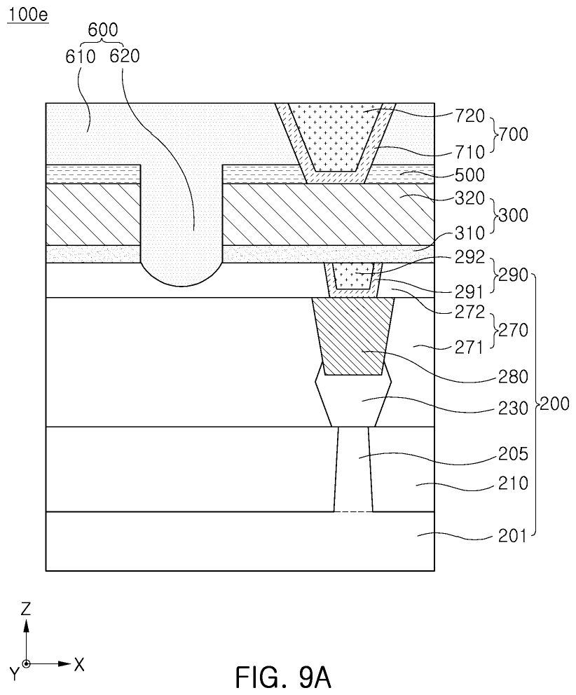

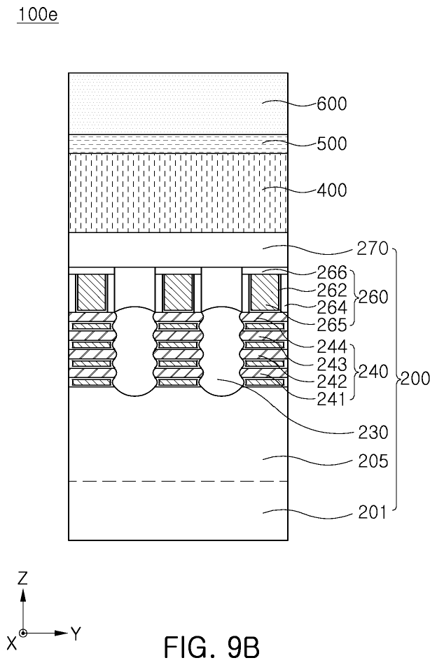

FIGS. 9A to 9B are cross-sectional views illustrating semiconductor devices according to example embodiments. FIGS. 9A to 9B illustrate various configurations that may be disposed on the top and bottom of the plurality of conductive wirings 300. FIG. 9A corresponds to a cross-section of the semiconductor device of FIG. 1 along cutting line II-II′, and FIG. 9B corresponds to a cross-section of the semiconductor device of FIG. 1 along a line perpendicular to cutting line II-II′.

Referring to FIGS. 9A to 9B, the lower structure 200 may include a substrate 201, an active region 205, a device isolation layer 210, a source/drain region 230, a gate structure 260, a lower insulating layer 270, and a contact plug 280. The lower structure 200 may further include a device isolation layer 210 and a connection via 290. The lower insulating layer 270 may include a first lower insulating layer 271 and a second lower insulating layer 272.

The substrate 201 may have an upper surface extending in the X and Y-directions. The substrate 201 may include a semiconductor material, such as a group IV semiconductor, a group III-V compound semiconductor, or a group II-VI compound semiconductor. For example, Group IV semiconductors may include silicon, germanium, or silicon-germanium. The substrate 101 may be provided as a bulk wafer, an epitaxial layer, a Silicon On Insulator (SOI) layer, or a Semiconductor On Insulator (SeOI) layer.

The substrate 201 may include active regions 205 disposed thereon. However, depending on an explanation method, the active regions 205 may be described as a separate configuration from the substrate 201.

The active regions 205 may be arranged to extend lengthwise in a second direction, for example, the Y-direction. Active regions 205 may be defined in a portion of the substrate 201 at a predetermined depth from the upper surface. The active regions 205 may be formed as part of the substrate 201 (e.g., formed by etching the substrate 201) or may be formed on the substrate 201 (e.g., an epitaxial layer grown from the substrate 201). Each of the active regions 205 may include active fins protruding upward. The active regions 205 together with the channel structures 240 may form an active structure in which a channel region of a transistor is formed. Each of the active regions 205 may include an impurity region. The impurity region may form at least a portion of the well region of the transistor.

A device isolation layer 210 may be positioned between adjacent active regions 205 in the X-direction. Upper surfaces of the active regions 205 may be located at a higher level than the upper surface of the device isolation layer 210. The active regions 205 may be partially recessed on at least one side of the gate structure 260, and source/drain regions 230 may be disposed on the recessed regions.

The device isolation layer 210 fills the space between the active regions 205 and may define the active regions 205 in the substrate 201. The device isolation layer 210 may be formed by, for example, a shallow trench isolation (STI) process. The device isolation layer 210 may expose the upper surface of the active region 205 and may partially expose the upper portion. The device isolation layer 210 may be made of an insulating material. The device isolation layer 210 may include, for example, oxide, nitride, or combinations thereof.

The gate structures 260 may be arranged on the active region 205 to intersect the active region 205 and extend lengthwise in a first direction (e.g., X-direction). Channel regions of transistors may be formed in the active region 205 and the channel structure 240 that intersect the gate electrodes 265 of the gate structures 260. Some of the gate structures 260 may be arranged in a straight line in the Y-direction and spaced apart from each other.

Each of the gate structures 260 may include gate dielectric layers 262, gate spacer layers 264, and gate electrode 265. Depending on an example embodiment, each of the gate structures 260 may further include a capping layer 266 on the upper surface of the gate electrode 265. Alternatively, a portion of the lower insulating layer 270 on the gate structures 260 may be referred to as a gate capping layer.

Gate dielectric layers 262 may be disposed between the active region 205 and the gate electrode 265 and between the channel structure 240 and the gate electrode 265, and may be arranged to cover at least some of the surfaces of the gate electrode 265. For example, the gate dielectric layers 262 may be arranged to surround all surfaces of the gate electrode 265 except the upper surface. The gate dielectric layers 262 may extend between the gate electrode 265 and the gate spacer layers 264, but are not limited thereto. The gate dielectric layer 262 may include oxide, nitride, or a high-k material. The high dielectric constant material may refer to a dielectric material having a higher dielectric constant than a silicon oxide film (SiO₂). The high dielectric constant material may be formed of or include any one of, for example, aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide. (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), and praseodymium oxide (Pr₂O₃). Depending on example embodiments, the gate dielectric layer 262 may have a multilayer structure.

The gate electrode 265 may include a conductive material, and for example, may include a metal nitride such as titanium nitride (TiN), tantalum nitride (TaN), or tungsten nitride (WN), and/or a metallic material such as aluminum (Al), tungsten (W), or molybdenum (Mo), or a semiconductor material such as doped polysilicon. Depending on example embodiments, the gate electrode 165 may have a multilayer structure.

Gate spacer layers 264 may be disposed on both sides of the gate electrode 265 on the channel structure 240. Gate spacer layers 264 may insulate the source/drain region 230 and the gate electrodes 265. Depending on an example embodiment, the shape of the top of the gate spacer layers 264 may be changed in various ways, and the gate spacer layers 264 may have a multi-layer structure. The gate spacer layers 264 may include at least one of oxide, nitride, and oxynitride, and may be formed of, for example, a low dielectric constant film.

Channel structures 240 may be disposed on the active regions 205 in regions where the active regions 205 intersect the gate structure 260. Each of the channel structures 240 may include first to fourth channel layers 241, 242, 243, and 244, which are two or more channel layers spaced apart from each other in the Z-direction by the gate structure 260. For example, each of the channel structures 240 may further include a plurality of channel layers 241, 242, 243, and 244 spaced apart from each other on the active region 205 in a third direction (e.g., Z-direction) perpendicular to the first direction (e.g., X-direction) and the second direction (e.g., Y-direction) and surrounded by the gate structure 260. Channel structures 240 may be connected to source/drain regions 230. The channel structures 240 may have a width equal to or smaller than the active region 205 in the Y-direction. In a cross section in the Y-direction, the channel layer disposed at the lower portion of the first to fourth channel layers 241, 242, 243, and 244 may have a width equal to or greater than that of the channel layer disposed at the upper portion.

The channel structures 240 may be made of a semiconductor material, and may be formed of or include, for example, at least one of silicon (Si), silicon germanium (SiGe), and germanium (Ge). For example, the channel structures 240 may be formed of the same material as the active regions 205. The number and shape of channel layers forming one channel structure 240 may vary in various embodiments.

The semiconductor device 100 may include a transistor having a Multi Bridge Channel FET (MBCFET™) structure, which is a gate-all-around type field effect transistor. However, in some embodiments, the semiconductor device 100 may not include the channel structures 240 and, for example, may have a FinFET structure.

The source/drain regions 230 may be disposed on at least one side of the gate structure 260 to contact the channel structures 240. The source/drain region 230 may be disposed in areas where the upper portion of the active region 205 is partially recessed. As illustrated in FIG. 9A, the source/drain region 230 may be electrically connected to the upper conductive structure 700 through a contact plug 280 and a plurality of conductive wirings 300.

The source/drain region 230 may have a polygonal shape as illustrated in FIG. 9 or an elliptical shape in a cross-section in the Y-direction, but is not limited to the shape illustrated. The source/drain region 230 may include a semiconductor material, for example, silicon (Si) and/or germanium (Ge), and may further include impurities.

The contact plug 280 may be electrically connected to a plurality of conductive wirings 300 within the lower structure 200, and the contact plug 280 may be disposed on the source/drain region 230. The contact plug 280 may penetrate the first lower insulating layer 271 and be connected to the source/drain regions 230. An upper surface of the contact plug 280 may be coplanar with an upper layer of the first lower insulating layer 271. The contact plug 280 may contact the source/drain region 230. The contact plug 280 may have an inclined side surface so that its width decreases toward the substrate 201 due to the aspect ratio, but the contact plug 280 is not limited thereto. The contact plug 280 may be disposed to partially recess the source/drain regions 230 so as to contact some of the surfaces including the upper surface of the source/drain regions 230. For example, a lower surface of the contact plug 280 may be at a lower level than an upper surface of the source/drain region 230. Accordingly, a portion of the contact plug 280 may be arranged to overlap a portion of the source/drain region 230 in the first direction (X-direction).

The contact plug 280 may include a metal silicide layer located at the bottom of each, and may further include a barrier disposed on the metal silicide layer and sidewalls. For example, the barrier may include a metal nitride such as titanium nitride (TiN), tantalum nitride (TaN), or tungsten nitride (WN). For example, the contact plug 280 may include a metal material such as aluminum (Al), tungsten (W), or molybdenum (Mo). In example embodiments, the number and arrangement of conductive layers constituting the contact plug 280 may vary.

The connection via 290 may penetrate the second lower insulating layer 272 disposed on the first lower insulating layer 271 to electrically connect the contact plug 280 and the conductive wiring 300. The connection via 290 may include a connection barrier layer 291 and a connection conductive layer 292. The connection barrier layer 291 may contact side and lower surfaces of the connection conductive layer 292. A lower surface of the connection barrier layer 291 may contact an upper surface of the contact plug 280.

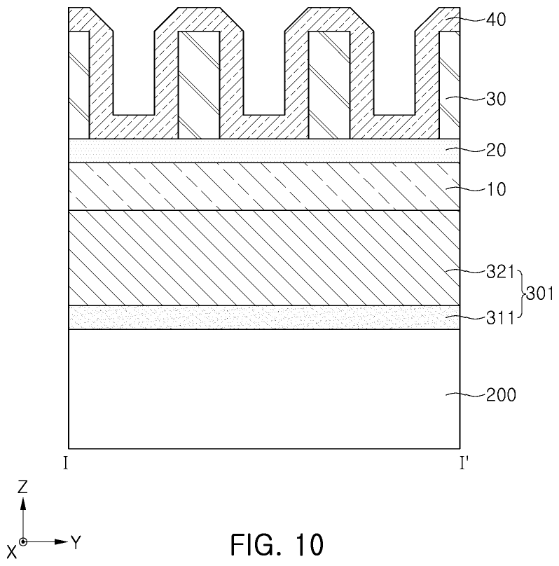

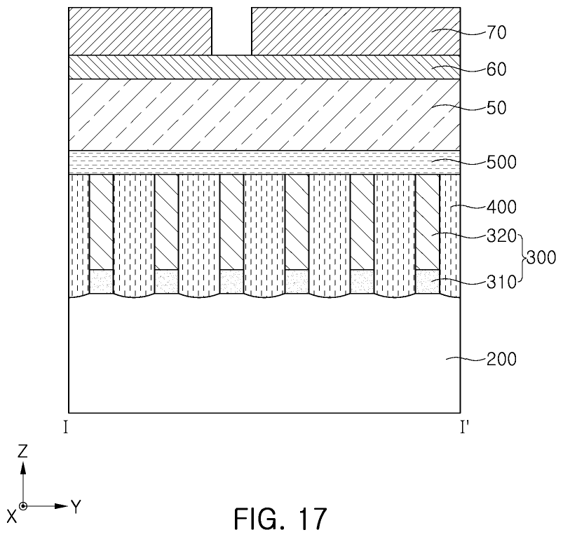

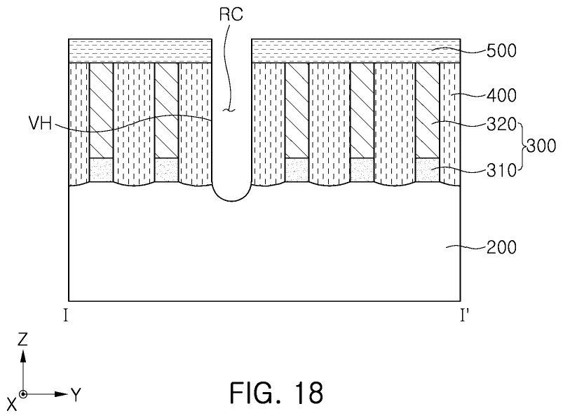

FIGS. 10 to 18 are diagrams illustrating a process sequence to explain a method of manufacturing a semiconductor device according to example embodiments. FIGS. 10 to 18 illustrate an example embodiment of a manufacturing method for manufacturing the semiconductor device of FIGS. 1 to 3 and illustrate a cross section corresponding to FIG. 2.

Referring to FIG. 10, a conductive layer 301 may be formed on the lower structure 200. The conductive layer 301 may include a preliminary barrier layer 311 and a preliminary wiring layer 321 on the preliminary barrier layer 311.

The first mask layer 10 may be formed on the conductive layer 301. The first mask layer 10 may include a material that has an etch selectivity with that of the conductive layer 301. The first mask layer 10 may include silicon nitride. For example, the first mask layer 10 may include SiN.

The second mask layer 20 may be formed on the first mask layer 10. The second mask layer 20 may include silicon oxide.

The silicon patterns 30 may be formed on the second mask layer 20. The silicon patterns 30 extend lengthwise in the X-direction and may be formed to be spaced apart from each other in the Y-direction. The silicon pattern 30 may include amorphous silicon (Amorphous-Si).

The preliminary spacer pattern 40 may be formed to extend and cover a portion of the upper surface of the second mask layer 20 and the side and upper surfaces of the silicon pattern 30. The preliminary spacer pattern 40 may include a material having an etch selectivity with respect to the conductive layer 301, the silicon patterns 30, the second mask layer 20, and the first mask layer 10. The preliminary spacer pattern 40 may include titanium oxide. For example, the preliminary spacer pattern 40 may include TiO₂.

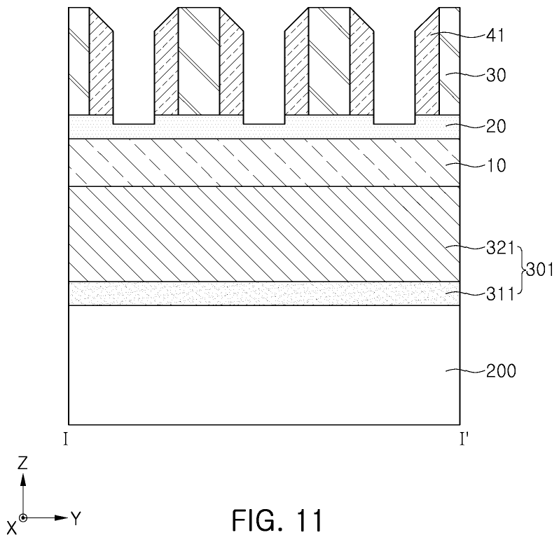

Referring to FIG. 11, a spacer pattern 41 may be formed by etching a portion of the preliminary spacer pattern 40. The spacer pattern 41 may be formed by etching the remaining portion of the preliminary spacer pattern 40 excluding the preliminary spacer pattern 40 on the side of the silicon pattern 30. In the process of forming the spacer pattern 41, the exposed portion of the upper surface of the second mask layer 20 may be etched together.

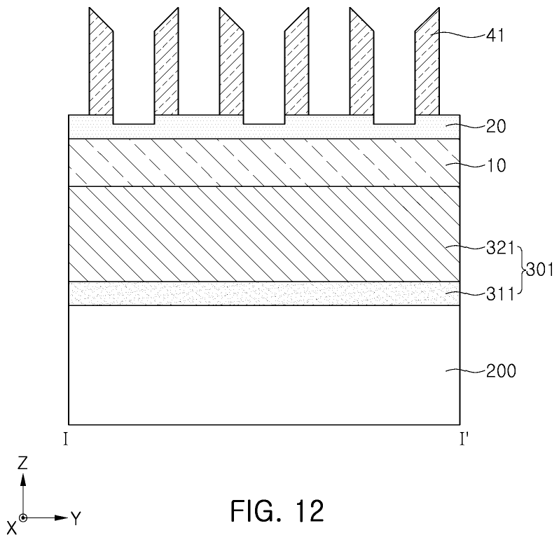

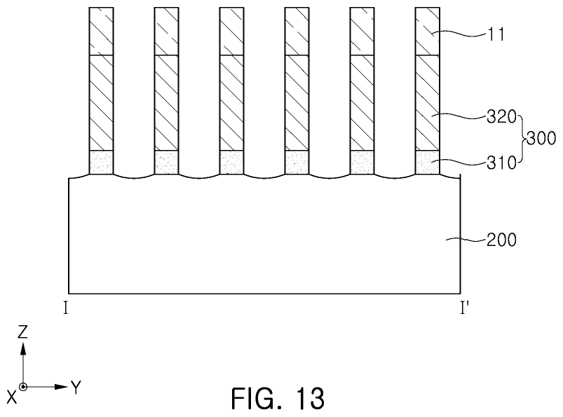

Referring to FIGS. 12 to 13, the silicon pattern 30 is removed by etching, and portions of the second mask layer 20, the first mask layer 10, and the conductive layer 301 that do not overlap the spacer pattern 41 in the Z-direction may be etched. Afterwards, both the second mask layer 20 and the spacer pattern 41 may be removed. Accordingly, a portion of the first mask layer 10 that overlaps the spacer pattern 41 in the Z-direction forms the first mask pattern 11, and a portion of the conductive layer 301 that overlaps the spacer pattern 41 in the Z-direction may form a plurality of conductive wirings 300. The plurality of conductive wirings 300 may include a barrier layer 310 and a wiring layer 320 on the barrier layer 310. In this process, a portion of the upper surface of the lower structure 200 that does not overlap the spacer pattern 41 in the Z-direction may be etched. When the conductive layer 301 contains ruthenium (Ru), etching of the conductive layer 301 may be performed by a dry etching process.

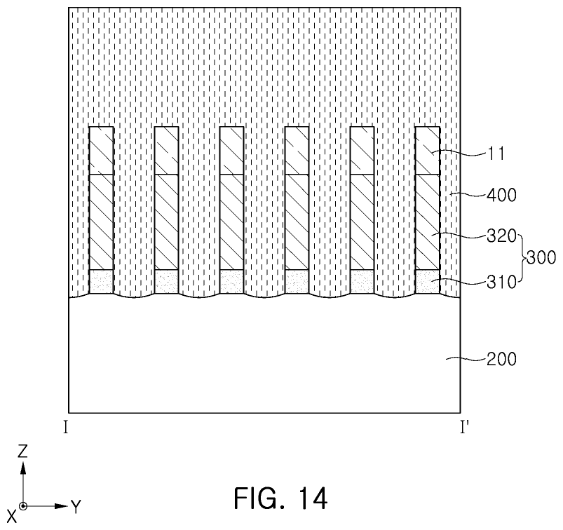

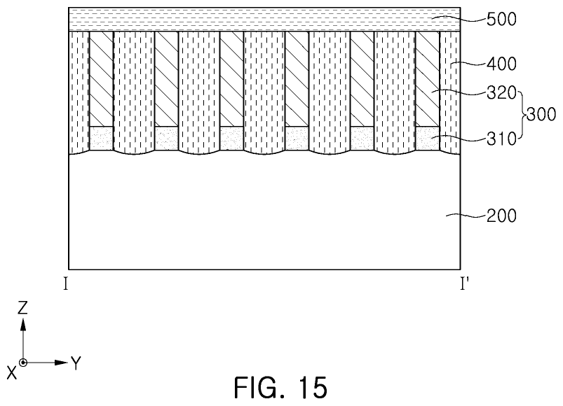

Referring to FIGS. 14 to 15, an interlayer insulating layer 400 may be formed to cover the upper surface of the lower structure 200, the side surfaces of the plurality of conductive wirings 300, and the side and upper surfaces of the first mask pattern 11. Thereafter, the portion of the interlayer insulating layer 400 located at a level higher than the upper surface of the plurality of conductive wirings 300 and the entire first mask pattern 11 may be removed. For example, the portion of the interlayer insulating layer 400 and the first mask pattern 11 located at a level higher than the upper surface of the plurality of conductive wirings 300 may be removed through an ashing process. Accordingly, the upper surfaces of the plurality of conductive wirings 300 and the interlayer insulating layer 400 may be located at substantially the same level. The protective insulating layer 500 may be disposed on the upper surface of the plurality of conductive wirings 300 and the interlayer insulating layer 400. The protective insulating layer 500 may be formed by, for example, an atomic layer deposition (ALD) process.

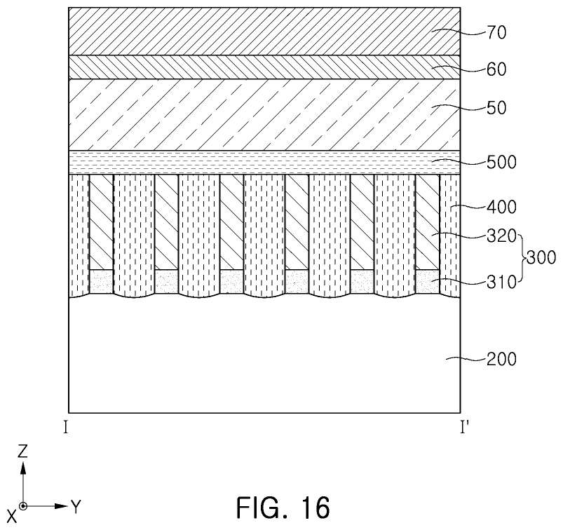

Referring to FIGS. 16 to 18, a third mask layer 50, a fourth mask layer 60, and a resist layer 70 may be sequentially formed on the protective insulating layer 500. A recess region RC may be formed to remove the protective insulating layer 500 that overlaps the conductive wiring to be etched (for example, the first conductive wiring) among the plurality of conductive wirings 300 in the Z-direction. The recess region RC may be formed to extend into the interior of the lower structure 200 through the protective insulating layer 500, the conductive wiring, and the interlayer insulating layer 400. In addition, referring to FIG. 2, the upper insulating structure 600 may be formed to fill the recess region RC and cover the upper surface of the protective insulating layer 500. A portion of the upper insulating structure 600 formed on the protective insulating layer 500 forms an upper interlayer portion 610, and a portion of the upper insulating structure 600 that fills the recess region RC may form an extension portion 620. By first forming a plurality of conductive wirings 300 and then performing a cut process to form a recess region (RC), even when the width of each of the plurality of conductive wirings 300 is formed to be 24 nm or less due to the high integration of semiconductor devices, a pattern of a plurality of conductive wirings 300 may be formed.

As set forth above, by including a structure in which a cut process is performed after forming conductive wirings, a semiconductor device having improved integration and electrical characteristics may be provided.

While example embodiments have been illustrated and described above, it will be apparent to those skilled in the art that modifications and variations could be made without departing from the scope of the present inventive concept as defined by the appended claims.

What is claimed is:

1. A semiconductor device comprising:
a lower structure;
a plurality of conductive wirings on the lower structure;
an interlayer insulating layer on the lower structure and on side surfaces of the plurality of conductive wirings;
a protective insulating layer on the interlayer insulating layer and the plurality of conductive wirings; and
an upper insulating structure,
wherein the upper insulating structure includes an upper interlayer portion on the protective insulating layer, and an extension portion extending from the upper interlayer portion, penetrating through the protective insulating layer, the interlayer insulating layer, and a first conductive wiring among the plurality of conductive wirings, and extending into the lower structure.

2. The semiconductor device of claim 1, wherein the first conductive wiring is divided into a first wiring portion and a second wiring portion spaced apart from each other by the extension portion.

3. The semiconductor device of claim 1, wherein each of the plurality of conductive wirings includes a barrier layer and a wiring layer on the barrier layer.

4. The semiconductor device of claim 3,
wherein the barrier layer includes metal nitride, and
wherein the wiring layer contains ruthenium (Ru).

5. The semiconductor device of claim 1,
wherein the plurality of conductive wirings extend in a first direction and are spaced apart in a second direction, intersecting the first direction, and
wherein a minimum distance between the plurality of conductive wirings in the second direction is 24 nm or less.

6. The semiconductor device of claim 1, further comprising:
an upper conductive structure penetrating through the upper interlayer portion and the protective insulating layer and electrically connected to one conductive wiring of the plurality of conductive wirings.

7. The semiconductor device of claim 6,
wherein each of the plurality of conductive wirings includes a first barrier layer and a first wiring layer on the first barrier layer,
wherein the first barrier layers include a first conductive material,
wherein the first wiring layers include a second conductive material, different from the first conductive material, and
wherein the extension portion of the upper insulating structure contacts side surfaces of the first barrier layers and side surfaces of the first wiring layers.

8. The semiconductor device of claim 7, wherein the second conductive material includes ruthenium (Ru).

9. The semiconductor device of claim 7,
wherein the upper conductive structure includes a second barrier layer and a second wiring layer on the second barrier layer, and
wherein the second barrier layer covers a side surface and a lower surface of the second wiring layer.

10. The semiconductor device of claim 9, wherein the second wiring layer includes a conductive material, different from the second conductive material.

11. The semiconductor device of claim 1, wherein a lower end of the first extension portion is located at a level lower than a level of a lower end of the interlayer insulating layer.

12. The semiconductor device of claim 1,
wherein the protective insulating layer includes a material different from a material of the interlayer insulating layer, and
wherein the material of the interlayer insulating layer contains a low-κ dielectric material.

13. The semiconductor device of claim 1, further comprising:
an etch stop layer between the lower structure and the interlayer insulating layer.

14. A semiconductor device comprising:
a lower structure;
a conductive wiring on the lower structure;
an interlayer insulating layer on the lower structure and disposed on a side surface of the conductive wiring; and
an upper insulating structure including an upper interlayer portion on the interlayer insulating layer, and an extension portion extending from the upper interlayer portion, penetrating through the interlayer insulating layer and the conductive wiring and dividing the conductive wiring into a first wiring portion and a second wiring portion spaced apart from each other.

15. The semiconductor device of claim 14,
wherein the first and second wiring portions respectively include a first barrier layer and a first wiring layer on the first barrier layer,
wherein the first barrier layers include a first conductive material,
wherein the first wiring layers include a second conductive material, different from the first conductive material, and
wherein the extension portion of the upper insulating structure contacts side surfaces of the first barrier layers and side surfaces of the first wiring layers.

16. The semiconductor device of claim 15, wherein the second conductive material includes ruthenium (Ru).

17. The semiconductor device of claim 15, further comprising:
an upper conductive structure electrically connected to at least one of the first wiring portion and the second wiring portion,
wherein the upper conductive structure includes a second barrier layer and a second wiring layer on the second barrier layer,
wherein the second barrier layer covers a side surface and a lower surface of the second wiring layer, and
wherein the second wiring layer is spaced apart from the upper insulating structure by the second barrier layer.

18. The semiconductor device of claim 14,
wherein the first wiring portion and the second wiring portion respectively have a bar shape or a line shape extending in a first direction,
wherein a width of each of the first and second wiring portions in a second direction is less than a width of the extension portion in the second direction, and
wherein the second direction is perpendicular to the first direction.

19. A semiconductor device comprising:
a lower structure including a substrate, a gate, an active region, a source/drain region, a lower insulating layer, and a contact plug;
a conductive wiring on the lower structure;
an interlayer insulating layer on the lower structure and on a side surface of the conductive wiring;
a protective insulating layer on the interlayer insulating layer and the conductive wiring; and
an upper insulating structure including an upper interlayer portion on the protective insulating layer, and an extension portion extending from the upper interlayer portion, penetrating through the protective insulating layer and the conductive wiring, and extending into an interior of the lower structure,
wherein the active region is on the substrate,
wherein the gate is provided on the active region and crosses the active region,
wherein the source/drain region is on at least one side of the gate and is disposed on the active region,
wherein the lower insulating layer covers at least a portion of the source/drain region, and
wherein the contact plug is on the source/drain region and is electrically connected to the conductive wiring.

20. The semiconductor device of claim 19, further comprising:
a plurality of channel layers on the active region and spaced apart from each other to be surrounded by the gate.
